(19) United States
(12) Patent Application Publication
(10) Pub. No.: US 2026/0093002 A1
(43) Pub. Date: Apr. 2, 2026

(54) SYSTEM AND METHOD FOR MAGNETIC RESONANCE GRADIENT SUBSYSTEM ERROR DETECTION

(71) Applicant: GE Precision Healthcare LLC, Waukesha, WI (US)

(72) Inventor: Barry Joseph Fetics, Wauwatosa, WI (US)

(21) Appl. No.: 18/901,337

(22) Filed: Sep. 30, 2024

(51) Int. Cl. G01R 33/565; G01R 33/58

(52) U.S. Cl. CPC G01R 33/56572; G01R 33/58

(57) ABSTRACT

A computer-implemented method for detecting an error with a magnetic resonance (MR) gradient subsystem includes acquiring, via a processing system including one or more processors, image data of a spherical phantom having an asymmetric feature during a scan utilizing an MR scanner having the MR gradient subsystem. The computer-implemented method also includes analyzing, via the processing system, pixel value distributions of the image data. The computer-implemented method further includes determining, via the processing system, whether the MR gradient subsystem has a hardware failure based on the analysis of the pixel value distributions. The computer-implemented method further includes determining, via the processing system, whether the MR gradient subsystem has an installation error based on the analysis of the measured orientation of a spherical phantom having an asymmetric feature with respect to its expected orientation.

### BACKGROUND

The subject matter disclosed herein relates to medical imaging and, more particularly, to a system and method for magnetic resonance (MR) subsystem error detection.

Non-invasive imaging technologies allow images of the internal structures or features of a patient/object to be obtained without performing an invasive procedure on the patient/object. In particular, such non-invasive imaging technologies rely on various physical principles (such as the differential transmission of X-rays through a target volume, the reflection of acoustic waves within the volume, the paramagnetic properties of different tissues and materials within the volume, the breakdown of targeted radionuclides within the body, and so forth) to acquire data and to construct images or otherwise represent the observed internal features of the patient/object.

During magnetic resonance imaging (MRI), when a substance such as human tissue is subjected to a uniform magnetic field (polarizing field B₀), the individual magnetic moments of the spins in the tissue attempt to align with this polarizing field, but precess about it in random order at their characteristic Larmor frequency. If the substance, or tissue, is subjected to a magnetic field (excitation field B₁) which is in the x-y plane and which is near the Larmor frequency, the net aligned moment, or “longitudinal magnetization”, M_{z}, may be rotated, or “tipped”, into the x-y plane to produce a net transverse magnetic moment, Mₜ. A signal is emitted by the excited spins after the excitation signal B₁ is terminated and this signal may be received and processed to form an image.

When utilizing these signals to produce images, magnetic field gradients (Gₓ, G_{y}, and G_{z}) are employed. Typically, the region to be imaged is scanned by a sequence of measurement cycles in which these gradient fields vary according to the particular localization method being used. The resulting set of received nuclear magnetic resonance (NMR) signals are digitized and processed to reconstruct the image using one of many well-known reconstruction techniques.

It is critical that the MR gradient subsystem is installed and operating properly, since it determines the spatial placement and classification of features within MR images (e.g., left side of brain versus right side of brain). Current methods can confirm proper installation and operation, but they cannot provide, in the presence of improper installation or operation, specific diagnoses of how the MR gradient subsystem is either installed improperly or not operating properly. A general method which provides precise diagnoses of how the MR gradient subsystem is either installed improperly or not operating properly would expedite the troubleshooting and resolution of the problem.

### BRIEF DESCRIPTION

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, a computer-implemented method for detecting an error with a magnetic resonance (MR) gradient subsystem is provided. The computer-implemented method includes acquiring, via a processing system including one or more processors, image data of a spherical phantom having an asymmetric feature during a scan utilizing an MR scanner having the MR gradient subsystem. The computer-implemented method also includes analyzing, via the processing system, pixel value distributions of the image data. The computer-implemented method further includes determining, via the processing system, whether the MR gradient subsystem has a hardware failure based on the analysis of the pixel value distributions.

In another embodiment, a system for detecting an error with a magnetic resonance (MR) gradient subsystem is provided. The system includes a memory encoding processor-executable routines. The system also includes a processing system including one or more processors and configured to access the memory and to execute the processor-executable routines, wherein the processor-executable routines, when executed by the processing system, cause the processing system to perform actions. The actions include acquiring image data of a spherical phantom having an asymmetric feature during a scan utilizing an MR scanner having the MR gradient subsystem; analyzing pixel value distributions of the image data; and determining whether the MR gradient subsystem has a hardware failure based on the analysis of the pixel value distributions.

In a further embodiment, a non-transitory computer-readable medium, the non-transitory computer-readable medium including processor-executable code that when executed by a processing system including one or more processors, causes the processing system to perform actions. The actions include acquire image data of a spherical phantom having an asymmetric feature during a scan utilizing an magnetic resonance (MR) scanner having an MR gradient subsystem. The actions also include analyzing pixel value distributions of the image data. The actions further include determining whether the MR gradient subsystem has a hardware failure based on the analysis of the pixel value distributions.

### BRIEF DESCRIPTION OF THE DRAWINGS

These and other features, aspects, and advantages of the present subject matter will become better understood when the following detailed description is read with reference to the accompanying drawings in which like characters represent like parts throughout the drawings, wherein:

FIG. 1 is a block diagram of an MRI apparatus, in accordance with aspects of the present disclosure;

FIG. 2 is a block diagram of a computing device, in accordance with aspects of the present disclosure;

FIG. 3 is a schematic diagram of a spherical phantom having an asymmetric feature in isolation, in accordance with aspects of the present disclosure;

FIG. 4 is a schematic diagram of a spherical phantom having an asymmetric feature placed in a holder in a proper orientation, in accordance with aspects of the present disclosure;

FIGS. 5A and 5B are a flow diagram of a method for detecting an error with an MR gradient subsystem, in accordance with aspects of the present disclosure;

FIG. 6 depicts examples of synthetic and native images acquired of a spherical phantom having an asymmetric feature, in accordance with aspects of the present disclosure;

FIG. 7 depicts examples of graphs of different types of pixel data of the image data in FIG. 6, in accordance with aspects of the present disclosure;

FIG. 8 depicts a feature analysis on image data of a spherical phantom having an asymmetric feature and a comparison of measured and expected orientations, in accordance with aspects of the present disclosure;

FIG. 9 depicts passing criteria for determining if an MR gradient subsystem is installed correctly, in accordance with aspects of the present disclosure; and

FIG. 10 is a graphical user interface on a display showing a report of an analysis as to whether an MR gradient subsystem is installed correctly, in accordance with aspects of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present subject matter, the articles “a,” “an,” “the,” and “said” are intended to mean that there are one or more of the elements. The terms “comprising,” “including,” and “having” are intended to be inclusive and mean that there may be additional elements other than the listed elements. Furthermore, any numerical examples in the following discussion are intended to be non-limiting, and thus additional numerical values, ranges, and percentages are within the scope of the disclosed embodiments.

Some generalized information is provided to provide both general context for aspects of the present disclosure and to facilitate understanding and explanation of certain of the technical concepts described herein.

The term processor, processing system, or processing unit, as used herein, refers to any type of processing unit that can carry out the required calculations needed for the various embodiments, such as single or multi-core: CPU, Accelerated Processing Unit (APU), Graphics Board, DSP, FPGA, ASIC or a combination thereof.

As used herein, the term “computing system” refers to an electronic computing device such as, but not limited to, a single computer, virtual machine, virtual container, host, server, laptop, and/or mobile device, or to a plurality of electronic computing devices working together to perform the function described as being performed on or by the computing system. As used herein, the terms “application”, “application module” (or “module”), “engine”, or “program”, or “plugin” refers to one or more sets of computer software instructions (e.g., computer programs and/or scripts) executable by one or more processors of a computing system to provide particular functionality. Computer software instructions can be written in any suitable programming languages, such as C, C++, C#, Pascal, Fortran, Perl, MATLAB, SAS, SPSS, JavaScript, AJAX, and JAVA. Such computer software instructions can comprise an independent application with data input and data display aspects (e.g., modules). Alternatively, the disclosed computer software instructions can be classes that are instantiated as distributed objects. The disclosed computer software instructions can also be component software, for example JAVABEANS or ENTERPRISE JAVABEANS. Additionally, the disclosed applications or engines can be implemented in computer software, computer hardware, or a combination thereof.

As used herein, the terms “automatic” and “automatically” refer to actions that are performed by a computing device or computing system (e.g., of one or more computing devices) without human intervention. For example, automatically performed functions may be performed by computing devices or systems based solely on data stored on and/or received by the computing devices or systems despite the fact that no human users have prompted the computing devices or systems to perform such functions. As but one non-limiting example, the computing devices or systems may make decisions and/or initiate other functions based solely on the decisions made by the computing devices or systems, regardless of any other inputs relating to the decisions. While aspects of the following discussion are provided in the context of medical imaging, it should be appreciated that the disclosed techniques are not limited to such medical contexts. Indeed, the provision of examples and explanations in such a medical context is only to facilitate explanation by providing instances of real-world implementations and applications. However, the disclosed techniques may also be utilized in other contexts, such as image reconstruction for non-destructive inspection of manufactured parts or goods (i.e., quality control or quality review applications), and/or the non-invasive inspection of packages, boxes, luggage, and so forth (i.e., security or screening applications). In general, the disclosed techniques may be useful in any imaging or screening context or image processing or photography field where a set or type of acquired data undergoes a reconstruction process to generate an image or volume.

The following description relates to systems and methods to detect MR gradient subsystem errors. In particular, a gradient calibration tool (e.g., calibration software program) may be executed during performance of an MRI system calibration (e.g., during installation of the system). The disclosed systems and methods provide a general technique to diagnose any single one or a combination the X, Y, and Z coils/axes of the MR gradient subsystem for failures (e.g., wrong polarity, wrong connectivity, or non-operation (e.g., no transient magnetic field generated). Both hardware failures and installation problems can be detected and diagnosed. The disclosed embodiments can provide a precise diagnosis of what is wrong with the MR gradient subsystem. The disclosed embodiments reduce cost by speeding up the troubleshooting process for incorrectly installed MR gradient subsystems or MR gradient subsystems with hardware failure. The disclosed embodiments also streamline the resolution process. Although discussed in the context of MRI, certain aspects of the technique related to detecting an error in installation may be utilized in any imaging modality where features in images must accurately reflect their spatial orientation or location in real three-dimensional space and that is determined by hardware aligned with three principal axes.

The disclosed embodiments include acquiring image data of a spherical phantom having an asymmetric feature during a scan utilizing an MR scanner having the MR gradient subsystem, analyzing pixel value distributions of the image data, and determining whether the MR gradient subsystem has a hardware failure based on the analysis of the pixel value distributions. In certain embodiments, the disclosed embodiments include outputting a user-perceptible indication (e.g., report) of the hardware failure and ceasing further analysis of the MR gradient subsystem (i.e., ceasing running the gradient calibration tool) when the MR gradient subsystem has a hardware failure. In certain embodiments, the disclosed embodiments include outputting which of an X-axis, a Y-axis, and/or a Z-axis of the MR gradient subsystem has the hardware failure in the user-perceptible indication.

In certain embodiments, when the MR gradient subsystem does not have any hardware failure, the disclosed embodiments include performing feature analysis on the image data (i.e., determining location of asymmetric feature), wherein during the scan the spherical phantom was arranged within the bore of the MR scanner in a multi-axis-component orientation where a line extending from the center of the spherical phantom to a central location of the asymmetric feature has a contribution from each of an X-axis component, a Y-axis component, and a Z-axis component, wherein each respective contribution from the X-axis component, the Y-axis component, and the Z-axis component is different and has a value that is not zero. In certain embodiments, the disclosed embodiments include determining a measured orientation of the spherical phantom, wherein the measured orientation includes measured respective contributions from the X-axis component, the Y-axis component, and the Z-axis component. In certain embodiments, the disclosed embodiments include comparing the measured orientation to an expected orientation of the spherical phantom, wherein the expected orientation includes expected respective contributions from the X-axis component, the Y-axis component, and the Z-axis component when the MR gradient subsystem is installed properly. In certain embodiments, the disclosed embodiments include determining that the MR gradient subsystem is installed properly when the measured orientation is within a preset threshold of the expected orientation. In certain embodiments, the disclosed embodiments include determining that the MR gradient subsystem is not installed properly when the measured orientation is outside a preset threshold of the expected orientation. In certain embodiments, the disclosed embodiments include outputting a user-perceptible indication that the MR gradient subsystem is not installed properly and which of an X-axis, a Y-axis, and/or a Z-axis of the MR gradient subsystem is not installed properly.

In disclosed embodiments, a system for detecting an error with a magnetic resonance (MR) gradient subsystem includes a memory encoding processor-executable routines. The system also includes a processing system including one or more processors and configured to access the memory and to execute the processor-executable routines, wherein the processor-executable routines, when executed by the processing system, cause the processing system to perform actions. The actions include acquiring image data of a spherical phantom having an asymmetric feature during a scan utilizing an MR scanner having the MR gradient subsystem; analyzing pixel value distributions of the image data; and determining whether the MR gradient subsystem has a hardware failure based on the analysis of the pixel value distributions.

In disclosed embodiments, a non-transitory computer-readable medium includes processor-executable code that when executed by a processing system including one or more processors causes the processing system to perform actions. The actions include acquiring image data of a spherical phantom having an asymmetric feature during a scan utilizing an magnetic resonance (MR) scanner having an MR gradient subsystem. The actions also include analyzing pixel value distributions of the image data. The actions further include determining whether the MR gradient subsystem has a hardware failure based on the analysis of the pixel value distributions.

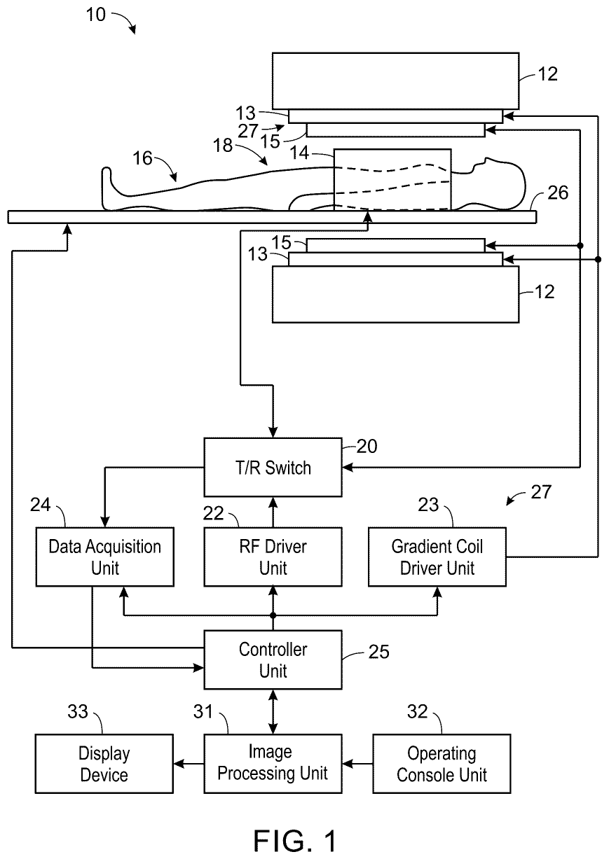

FIG. 1 illustrates an MRI apparatus 10 (e.g., an MRI system) that includes a magnetostatic field magnet unit 12, a gradient coil unit 13, an RF coil unit 14, an RF body coil unit 15 (e.g., volume coil unit), a transmit/receive (T/R) switch 20, an RF driver unit 22, a gradient coil driver unit 23, a data acquisition unit 24, a controller unit 25, a patient bed or table 26, a data processing unit 31, a scan control device 32, and a display unit 33. In some embodiments, the RF coil unit 14 is a surface coil, which is a local coil typically placed proximate to the anatomy of interest of a subject 16. Herein, the RF body coil unit 15 is a transmit coil that transmits RF signals, and the local surface of the RF coil unit 14 receives the MR signals. As such, the transmit body coil (e.g., RF body coil unit 15) and the surface receive coil (e.g., RF coil unit 14) are separate but electromagnetically coupled components. The MRI apparatus 10 transmits electromagnetic pulse signals to the subject 16 placed in an imaging space 18 with a static magnetic field formed to perform a scan for obtaining magnetic resonance signals from the subject 16. One or more images of the subject 16 can be reconstructed based on the magnetic resonance signals thus obtained by the scan.

The magnetostatic field magnet unit 12 includes, for example, an annular superconducting magnet, which is mounted within a toroidal vacuum vessel. The magnet defines a cylindrical space surrounding the subject 16 and generates a constant primary magnetostatic field B₀.

The MRI apparatus 10 also includes a gradient coil unit 13 that forms a gradient magnetic field in the imaging space 18 so as to provide the magnetic resonance signals received by the RF coil arrays with three-dimensional positional information. The gradient coil unit 13 includes three gradient coil systems, each of which generates a gradient magnetic field along one of three spatial axes perpendicular to each other, and generates a gradient field in each of a frequency encoding direction, a phase encoding direction, and a slice selection direction in accordance with the imaging condition. More specifically, the gradient coil unit 13 applies a gradient field in the slice selection direction (or scan direction) of the subject 16, to select the slice; and the RF body coil unit 15 or the local RF coil arrays may transmit an RF pulse to a selected slice of the subject 16. The gradient coil unit 13 also applies a gradient field in the phase encoding direction of the subject 16 to phase encode the magnetic resonance signals from the slice excited by the RF pulse. The gradient coil unit 13 then applies a gradient field in the frequency encoding direction of the subject 16 to frequency encode the magnetic resonance signals from the slice excited by the RF pulse.

The RF coil unit 14 is disposed, for example, to enclose the region to be imaged of the subject 16. In some examples, the RF coil unit 14 may be referred to as the surface coil or the receive coil. In the static magnetic field space or imaging space 18 where a static magnetic field B₀ is formed by the magnetostatic field magnet unit 12, the RF body coil unit 15 transmits, based on a control signal from the controller unit 25, an RF pulse that is an electromagnet wave to the subject 16 and thereby generates a high-frequency magnetic field B₁. This excites a spin of protons in the slice to be imaged of the subject 16. The RF coil unit 14 receives, as a magnetic resonance signal, the electromagnetic wave generated when the proton spin thus excited in the slice to be imaged of the subject 16 returns into alignment with the initial magnetization vector. In some embodiments, the RF coil unit 14 may transmit the RF pulse and receive the MR signal. In other embodiments, the RF coil unit 14 may only be used for receiving the MR signals, but not transmitting the RF pulse.

The RF body coil unit 15 is disposed, for example, to enclose the imaging space 18, and produces RF magnetic field pulses orthogonal to the main magnetic field B₀ produced by the magnetostatic field magnet unit 12 within the imaging space 18 to excite the nuclei. In contrast to the RF coil unit 14, which may be disconnected from the MRI apparatus 10 and replaced with another RF coil unit, the RF body coil unit 15 is fixedly attached and connected to the MRI apparatus 10. Furthermore, whereas local coils such as the RF coil unit 14 can transmit to or receive signals from only a localized region of the subject 16, the RF body coil unit 15 generally has a larger coverage area. The RF body coil unit 15 may be used to transmit or receive signals to the whole body of the subject 16, for example. Using receive-only local coils and transmit body coils provides a uniform RF excitation and good image uniformity at the expense of high RF power deposited in the subject. For a transmit-receive local coil, the local coil provides the RF excitation to the region of interest and receives the MR signal, thereby decreasing the RF power deposited in the subject. It should be appreciated that the particular use of the RF coil unit 14 and/or the RF body coil unit 15 depends on the imaging application.

The T/R switch 20 can selectively electrically connect the RF body coil unit 15 to the data acquisition unit 24 when operating in receive mode, and to the RF driver unit 22 when operating in transmit mode. Similarly, the T/R switch 20 can selectively electrically connect the RF coil unit 14 to the data acquisition unit 24 when the RF coil unit 14 operates in receive mode, and to the RF driver unit 22 when operating in transmit mode. When the RF coil unit 14 and the RF body coil unit 15 are both used in a single scan, for example if the RF coil unit 14 is configured to receive MR signals and the RF body coil unit 15 is configured to transmit RF signals, then the T/R switch 20 may direct control signals from the RF driver unit 22 to the RF body coil unit 15 while directing received MR signals from the RF coil unit 14 to the data acquisition unit 24. The coils of the RF body coil unit 15 may be configured to operate in a transmit-only mode or a transmit-receive mode. The coils of the RF coil unit 14 may be configured to operate in a transmit-receive mode or a receive-only mode.

The RF driver unit 22 includes a gate modulator (not shown), an RF power amplifier (not shown), and an RF oscillator (not shown) that are used to drive the RF coils (e.g., RF body coil unit 15) and form a high-frequency magnetic field in the imaging space 18. The RF driver unit 22 modulates, based on a control signal from the controller unit 25 and using the gate modulator, the RF signal received from the RF oscillator into a signal of predetermined timing having a predetermined envelope. The RF signal modulated by the gate modulator is amplified by the RF power amplifier and then output to the RF body coil unit 15.

The gradient coil driver unit 23 drives the gradient coil unit 13 based on a control signal from the controller unit 25 and thereby generates a gradient magnetic field in the imaging space 18. The gradient coil driver unit 23 includes three systems of driver circuits (not shown) corresponding to the three gradient coil systems included in the gradient coil unit 13. The gradient coil driver unit 23 and the gradient coil unit 13 form an MR gradient subsystem 27.

The data acquisition unit 24 includes a pre-amplifier (not shown), a phase detector (not shown), and an analog/digital converter (not shown) used to acquire the magnetic resonance signals received by the RF coil unit 14. In the data acquisition unit 24, the phase detector phase detects, using the output from the RF oscillator of the RF driver unit 22 as a reference signal, the magnetic resonance signals received from the RF coil unit 14 and amplified by the pre-amplifier, and outputs the phase-detected analog magnetic resonance signals to the analog/digital converter for conversion into digital signals. The digital signals thus obtained are output to the data processing unit 31.

The MRI apparatus 10 includes a table 26 for placing the subject 16 thereon. The subject 16 may be moved inside and outside the imaging space 18 by moving the table 26 based on control signals from the controller unit 25.

The controller unit 25 includes a computer and a recording medium on which a program to be executed by the computer is recorded. The program when executed by the computer causes various parts of the apparatus to carry out operations corresponding to predetermined scanning. The recording medium may comprise, for example, a ROM, flexible disk, hard disk, optical disk, magneto-optical disk, CD-ROM, or non-volatile memory card. The controller unit 25 is connected to the scan control device 32 and processes the operation signals input to the scan control device 32 and furthermore controls the table 26, RF driver unit 22, gradient coil driver unit 23, and data acquisition unit 24 by outputting control signals to them. The controller unit 25 also controls, to obtain a desired image, the data processing unit 31 and the display unit 33 based on operation signals received from the scan control device 32.

The scan control device 32 includes user input devices such as a touchscreen, keyboard and a mouse. The scan control device 32 is used by an operator, for example, to input such data as an imaging protocol and to set a region where an imaging sequence is to be executed. The data about the imaging protocol and the imaging sequence execution region are output to the controller unit 25.

The data processing unit 31 includes a computer and a recording medium on which a program to be executed by the computer to perform predetermined data processing is recorded. The data processing unit 31 is connected to the controller unit 25 and performs data processing based on control signals received from the controller unit 25. The data processing unit 31 is also connected to the data acquisition unit 24 and generates spectrum data by applying various image processing operations to the magnetic resonance signals output from the data acquisition unit 24.

The display unit 33 includes a display device and displays an image on the display screen of the display device based on control signals received from the controller unit 25. The display unit 33 displays, for example, an image regarding an input item about which the operator inputs operation data from the scan control device 32. The display unit 33 also displays a two-dimensional (2D) slice image or three-dimensional (3D) image of the subject 16 generated by the data processing unit 31.

During an MRI scan using the MRI apparatus 10, a subject may be positioned within the imaging space 18 and an acquisition protocol may be carried out to obtain MR signals of the subject. The acquisition protocol may include a plurality of pulse sequences where in each pulse sequence, contrast is prepared via one or more RF pulses applied by the RF body coil unit 15 and the gradient coil unit 13 is controlled to spatially encode the resultant MR signals. The spatially-encoded MR signals are received by the RF coil unit 14 are digitized and stored in k-space. Thus, k-space data or a k-space dataset may refer to the raw MR signals prior to processing into an image. In some examples, one line of k-space may be filled with the raw MR signals per pulse sequence (also referred to as repetition time). In other examples, one line of k-space may be filled with the raw MR signals per echo, where more than one echo is generated per pulse sequence/repetition time. The k-space data may also be referred to as imaging data or MR data herein.

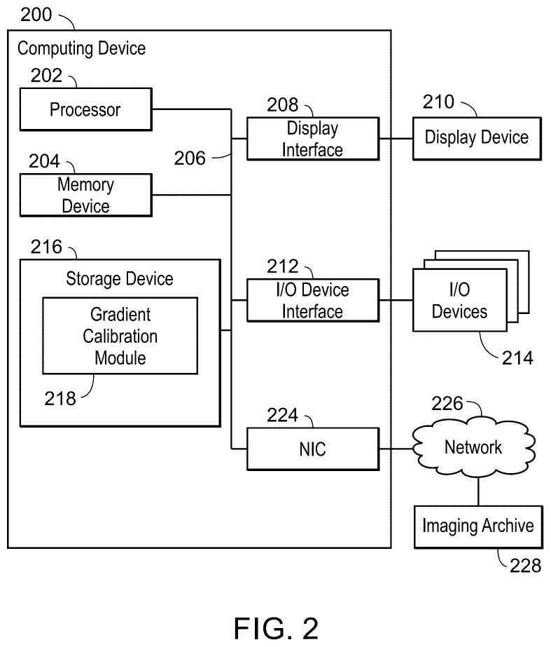

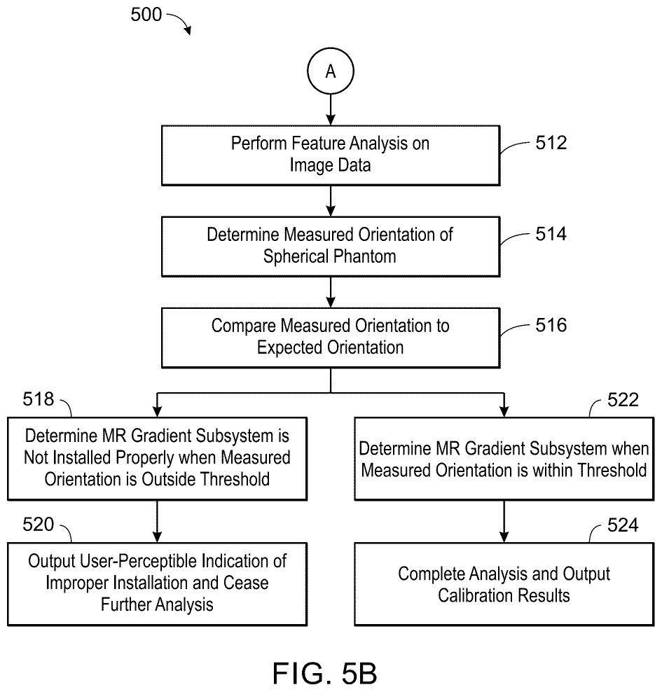

FIG. 2 is a block diagram of an example of a computing device 200 that can be utilized to detect MR gradient subsystem errors (e.g., during MRI system calibration). The computing device 200 may be, for example, part of a medical imaging system (e.g., MRI apparatus 10 in FIG. 1) or a separate computing device such as a hospital monitor, a laptop computer, a desktop computer, a tablet computer, or a mobile phone, among others. The computing device 200 may include a processor 202 that is adapted to execute stored instructions, as well as a memory device 204 that stores instructions that are executable by the processor 202. The processor 202 can be a single core processor, a multi-core processor, a computing cluster, or any number of other configurations. The memory device 204 can include random access memory, read only memory, flash memory, or any other suitable memory systems. The instructions that are executed by the processor 202 may be used to implement a method that can detect MR gradient subsystem errors, as described in greater detail below in relation to FIGS. 5A and 5B.

The processor 202 may also be linked through the system interconnect 206 (e.g., PCI, PCI-Express, NuBus, etc.) to a display interface 208 adapted to connect the computing device 200 to a display device 210. The display device 210 may include a display screen that is a built-in component of the computing device 200. The display device 210 may also include a computer monitor, television, or projector, among others, that is externally connected to the computing device 200. The display device 210 can include light emitting diodes (LEDs), and micro-LEDs, Organic light emitting diode OLED displays, among others.

The processor 202 may be connected through a system interconnect 206 to an input/output (I/O) device interface 212 adapted to connect the computing device 200 to one or more I/O devices 214. The I/O devices 214 may include, for example, a keyboard and a pointing device, wherein the pointing device may include a touchpad or a touchscreen, among others. The I/O devices 214 may be built-in components of the computing device 200, or may be devices that are externally connected to the computing device 200.

In some examples, the processor 202 may also be linked through the system interconnect 206 to a storage device 216 that can include a hard drive, an optical drive, a USB flash drive, an array of drives, or any combinations thereof. In some examples, the storage device 216 can include any suitable applications. In some examples, the storage device 216 can include a gradient calibration module 218 (or gradient calibration tool). The gradient calibration module 218 is configured to acquire image data of a spherical phantom having an asymmetric feature during a scan utilizing an MR scanner having the MR gradient subsystem, analyze pixel value distributions of the image data, and determine whether the MR gradient subsystem has a hardware failure based on the analysis of the pixel value distributions. In certain embodiments, the gradient calibration module 218 is configured to output (e.g., I/O devices 214) a user-perceptible indication (e.g., report) of the hardware failure and ceasing further analysis of the MR gradient subsystem (i.e., ceasing running the gradient calibration tool) when the MR gradient subsystem has a hardware failure. In certain embodiments, the gradient calibration module 218 is configured to output (e.g., I/O devices 214) which of an X-axis, a Y-axis, and/or a Z-axis of the MR gradient subsystem has the hardware failure in the user-perceptible indication.

In certain embodiments, when the MR gradient subsystem does not have any hardware failure, the gradient calibration module 218 is configured to perform feature analysis on the image data (i.e., determining location of asymmetric feature), wherein during the scan the spherical phantom was arranged within the bore of the MR scanner in a multi-axis-component orientation where a line extending from the center of the spherical phantom to a central location of the asymmetric feature has a contribution from each of an X-axis component, a Y-axis component, and a Z-axis component, wherein each respective contribution from the X-axis component, the Y-axis component, and the Z-axis component is different and has a value that is not zero. In certain embodiments, the gradient calibration module 218 is configured to determine a measured orientation of the spherical phantom, wherein the measured orientation incudes measured respective contributions from the X-axis component, the Y-axis component, and the Z-axis component. In certain embodiments, the gradient calibration module 218 is configured to compare the measured orientation to an expected orientation of the spherical phantom, wherein the expected orientation includes expected respective contributions from the X-axis component, the Y-axis component, and the Z-axis component when the MR gradient subsystem is installed properly. In certain embodiments, the gradient calibration module 218 is configured to determine that the MR gradient subsystem is installed properly when the measured orientation is within a preset threshold of the expected orientation. In certain embodiments, the gradient calibration module 218 is configured to determine that the MR gradient subsystem is not installed properly when the measured orientation is outside a preset threshold of the expected orientation. In certain embodiments, the gradient calibration module 218 is configured to output (e.g., I/O devices 214) a user-perceptible indication that the MR gradient subsystem is not installed properly and which of an X-axis, a Y-axis, and/or a Z-axis of the MR gradient subsystem is not installed properly.

In some examples, a network interface controller (also referred to herein as a NIC) 224 may be adapted to connect the computing device 200 through the system interconnect 206 to a network 226. The network 226 may be a cellular network, a radio network, a wide area network (WAN), a local area network (LAN), or the Internet, among others. The network 226 can enable data, such as alerts, among other data, to be transmitted from the computing device 200 to remote computing devices, remote display devices, and the like.

It is to be understood that the block diagram of FIG. 2 is not intended to indicate that the computing device 200 is to include all of the components shown in FIG. 2. Rather, the computing device 200 can include fewer or additional components not illustrated in FIG. 2 (e.g., additional memory components, embedded controllers, additional modules, additional network interfaces, etc.). Furthermore, any of the functionalities of the gradient calibration module 218 may be partially, or entirely, implemented in hardware and/or in the processor 202. For example, the functionality may be implemented with an application specific integrated circuit, logic implemented in an embedded controller, or in logic implemented in the processor 202, among others. In some examples, the functionalities of the gradient calibration module 218 can be implemented with logic, wherein the logic, as referred to herein, can include any suitable hardware (e.g., a processor, among others), software (e.g., an application, among others), firmware, or any suitable combination of hardware, software, and firmware.

In some examples, the computing device 200 may be incorporated into an imaging system, such as the MRI system 10. For example, the computing device 200 may be the image processing unit 31 of the MRI system 10. However, in other examples, the computing device 200 may be disposed at a device (e.g., a server, edge device, etc.) communicably coupled to the imaging system via wired and/or wireless connections. In some examples, at least a portion of computing device 200 may be disposed at a separate device (e.g., a workstation) which can receive images from the imaging system or from a storage device which stores the images generated by the imaging system and/or other additional imaging systems.

In addition to the image data directly provided by the computing device 200, image data may be further sourced from an imaging archive 228 communicatively coupled to the computing device 200. The imaging archive 228 may comprise, for example, a picture archiving and communication system (PACS), a vendor neutral archive (VNA), or other suitable medical image database. The medical imaging archive may be hosted on a remote server configured to allow the computing device 200 to access the plurality of medical images and patient data hosted thereon.

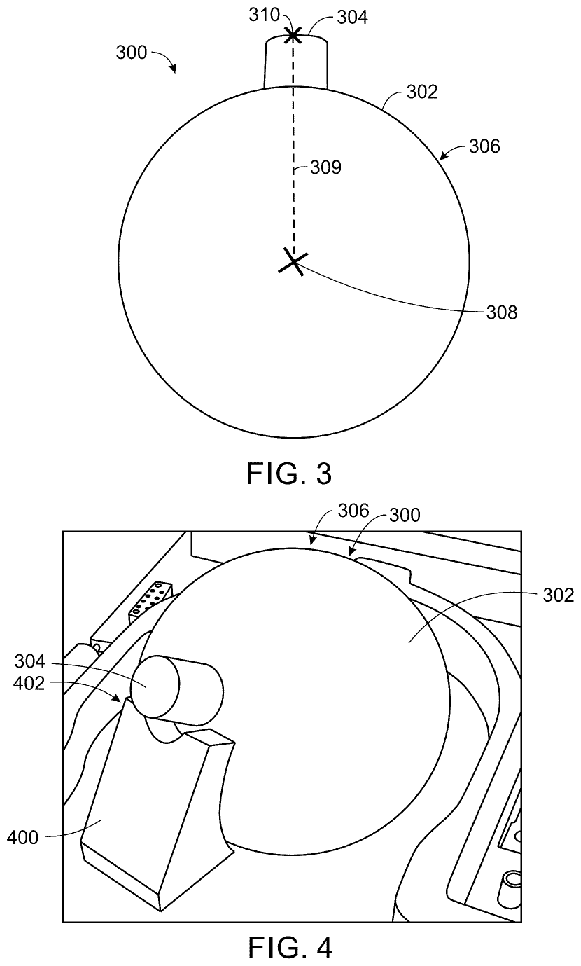

FIG. 3 is a schematic diagram of a spherical phantom 300 having an asymmetric feature in isolation. As described in greater detail below, the spherical phantom 300 is utilized in detecting any errors in an MR gradient subsystem during calibration of an MRI system. As depicted, the spherical phantom 300 has a main spherical portion 302 filled with a liquid that is detectable by MRI apparatus 10. In general, the spherical phantom 302 also includes a single asymmetric feature 304 (e.g., protrusion) located on a periphery 306 of the main spherical portion 302. The single asymmetric feature 304 is also filled with a liquid that is detectable by MR apparatus 10. Image data of the full volume of the spherical phantom 300 is acquired during a scan with an MR scanner with the spherical phantom 300 located within the bore of the MR scanner. The image data of the spherical phantom 300 is utilized in detecting errors in the MR gradient subsystem. For example, analysis of pixel value distributions of the image data of the spherical phantom 300 is utilized to determine a hardware failure.

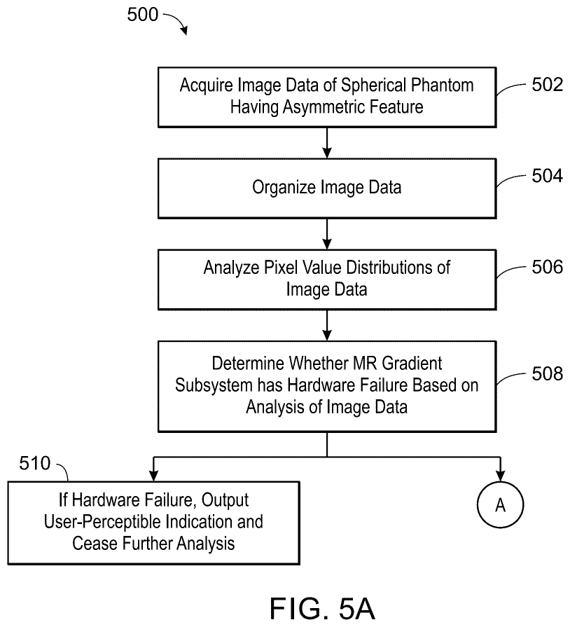

Also, feature analysis (i.e., determining the location of the asymmetric feature 304) of the image data is utilized to determine if there is an installation problem based on if the measured orientation of the spherical phantom 300 is similar enough to the expected orientation. In particular, during the scan of the spherical phantom 300, it is placed within a holder 400 in a specific expected location as depicted in FIG. 4. In particular, the spherical phantom 300 is placed in the holder 400 in a multi-axis component orientation. As depicted in FIG. 4, the holder 400 includes a notch 402 that the asymmetric feature 304 of the spherical phantom 300 is placed in to ensure that the spherical phantom 300 is in the multi-axis component orientation.

In geometry, the orientation of a line can be described by a unit vector [a,b,c], which is defined by:

$${a}^{2} + {b}^{2} + {c}^{2} = 1.0 , \qquad ( 1 )$$

where a, b, and c are the 3 components of the line. The asymmetric aspect of the spherical phantom 300 is placed in the multi-axis-component orientation in the holder 400 such that a line (e.g., dashed line 309 in FIG. 3) from the center 308 of the main spherical portion 302 of the spherical phantom 300 (ignoring the asymmetric feature 304) to a central location 310 of the asymmetric feature 304. The expected values of the components of the unit vector of the line 309 are as follows: a equals 0.2588, b equals 0.54399912144846, and c equals −0.798177621750512. The values of a, b, c, are unitless, i.e. they do not have associated with them a measurement unit like millimeter or kilogram. The value of a is associated with the desired X-axis content, the value of b is associated with the desired Y-axis content, and the value of c is associated with the desired Z-axis content. The orientation of the spherical phantom 300 is in this multi-axis-component orientation so that the 3 values of a, b, and c must be different from each other (i.e., unequal contributions) and no value is zero (for the purposes of polarity). In certain embodiments, the values of a, b, and c may be different as long as they are different from each other and none of the values is zero.

There are two aspects: the values of a, b, and c and also the signs (e.g., plus or minus) of a, b, and c. With respect to value, the following has been demonstrated via empirical data. For example, if the wiring of X and Y gradient subsystems are swapped, then the a value will appear in the result for the Y-axis and the b value will appear in the result of the X-axis, which is a swap that can be identified. It has been demonstrated that this is a general result for all 5 possible axis swaps, not just X and Y in the example above. This is call “wiring”. Value determines wiring.

With respect to sign, the following has been demonstrated via simulated data. For example, if the polarity of the X gradient subsystem is wrong, the sign of a (expected to be positive as shown above) will appear in the result as the opposite to the expected (i.e., it will appear negative). This has been demonstrated for all 3 axes. This is called “polarity”. Sign determines polarity.

Ranges (e.g., thresholds) are utilized in the unit vector analysis of the orientation. As can be easily derived from a comparison of the a, b, c values above, the absolute values of a, b, and c are separated by greater than 0.25. Half of this value is 0.125. Therefore, for example, for the measured first unit vector value to qualify as X-axis content, it does not have to be exactly the value of 0.2588. It can be any value in the range of 0.1338 to 0.3838, which are respectively (0.2588−0.125) and (0.2588+0.125). The same applies to the measured second and third unit vector values. This makes it a practical technique with an allowed tolerance for placement. The allowed threshold or range may vary but must be less than half of the smallest separation.

FIGS. 5A and 5B depict a flow diagram of a method 500 for detecting an error with an MR gradient subsystem. One or more steps of the method 500 may be performed by processing circuitry of the MRI apparatus 10 in FIG. 1. The method 500 is performed subsequent to placing the spherical phantom 300 in the holder 400 (depicted in FIG. 3) into the bore of an MR scanner.

The method 500 includes acquiring image data of a spherical phantom having an asymmetric feature during a scan utilizing an MR scanner having the MR gradient subsystem (block 502). The scan is of a full volume of the spherical phantom. The method 500 also includes organizing the image data (block 504). For example, the image data is put into a three-dimensional matrix. The method 500 further includes analyzing pixel value distributions of the image data (block 506).

The method 500 includes determining whether the MR gradient subsystem has a hardware failure based on the analysis of the pixel value distributions (block 508). If maximum pixel values exist within the pixel value distributions, then a hardware failure exists with respect to the MR gradient subsystem. The method 500 includes outputting a user-perceptible indication (e.g., report) of the hardware failure and ceasing further analysis of the MR gradient subsystem (i.e., ceasing running calibration gradient tool) when the MR gradient subsystem has a hardware failure (block 510). The outputted user-perceptible indication includes which of an X-axis, a Y-axis, and/or a Z-axis of the MR gradient subsystem has the hardware failure. One or more the axes of the MR gradient subsystem may have a hardware failure. It should be noted that analysis for the hardware failure does not require object detection or feature/shape/size analysis. The only items taken into account are the pixel values and their distributions.

The method 500 includes, when the MR gradient subsystem does not have any hardware failure, performing feature analysis on the image data (block 512). During the scan, the spherical phantom was arranged within the bore of the MR scanner in a multi-axis-component orientation where a line extending from the center of the spherical phantom to a central location of the asymmetric feature has a contribution from each of an X-axis component, a Y-axis component, and a Z-axis component, wherein each respective contribution from the X-axis component, the Y-axis component, and the Z-axis component is different and has a value that is not zero. The feature analysis includes determining the location of the asymmetric feature of the spherical phantom relative to the center of the main spherical portion of the spherical phantom.

The method 500 also includes determining a measured orientation of the spherical phantom (e.g., based on feature analysis), wherein the measured orientation includes measured respective contributions from the X-axis component, the Y-axis component, and the Z-axis component (block 514). Determining the measured orientation includes determining the values and signs of the different components of unit vector of the line. The method 500 further includes comparing the measured orientation to an expected orientation of the spherical phantom, wherein the expected orientation includes expected respective contributions (e.g., expected sign and values as shown with respect to a, b, c as noted above in the discussion of FIGS. 3 and 4) from the X-axis component, the Y-axis component, and the Z-axis component when the MR gradient subsystem is installed properly (block 516). The method 500 even further includes determining that the MR gradient subsystem is not installed properly when the measured orientation (e.g., at least one component measurement) is outside a preset threshold (range) of the expected orientation (block 518). The method 500 includes outputting a user-perceptible indication (e.g., report) that the MR gradient subsystem is not installed properly and ceasing further analysis of the MR gradient subsystem (i.e., ceasing running calibration gradient tool) (block 520). The user-perceptible indication includes which of an X-axis, a Y-axis, and/or a Z-axis of the MR gradient subsystem is not installed properly. One or more of the axes of the MR gradient subsystem may not be installed properly. The method 500 also includes determining that the MR gradient subsystem is installed properly when the measured orientation is within a preset threshold of the expected orientation (block 522). When the MR gradient subsystem is installed properly, the method 500 includes completing the analysis and outputting calibration results (block 524). It should be noted that analysis for installation failure does not require analysis of the unit vector relative to principal axes but only of the components of the unit vector itself.

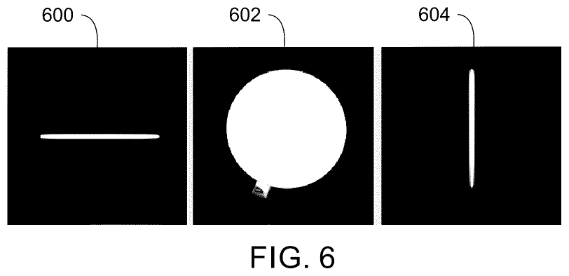

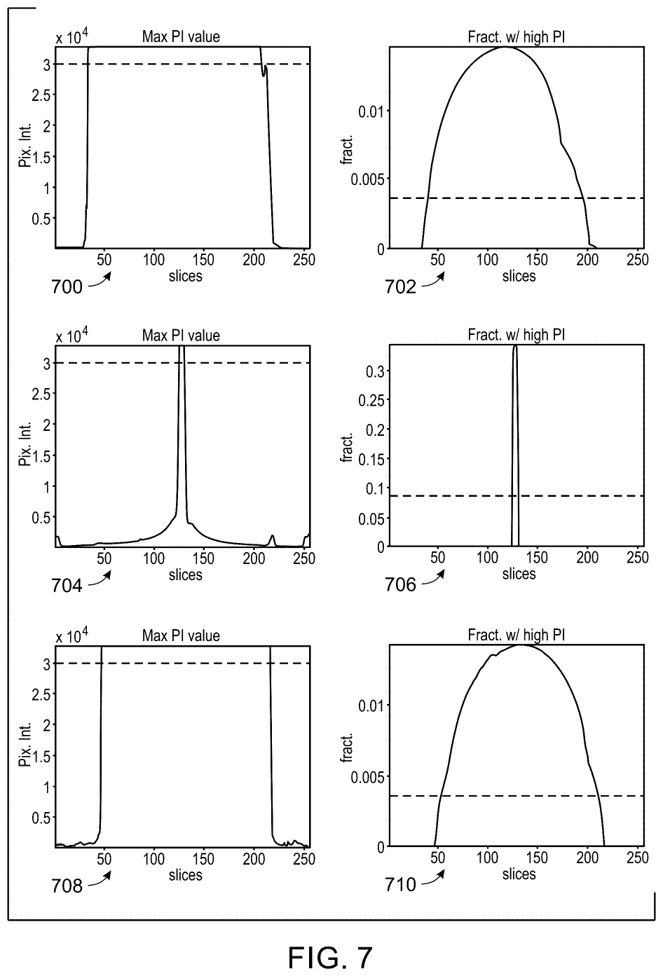

FIG. 6 depicts examples of images 600, 602, 604 that can be obtained from a single 3D image set of the spherical phantom having the asymmetric feature, when three different dimensions of the 3D image set are used as the “depth” dimension. Images 600 and 602 are synthetic in that they are obtained by querying the 3D image set in different ways, while image 604 is an acquired image; all such images are valid for analysis. FIG. 6 is an example of data consisting of a gradient subsystem failure. FIG. 6 represents an intermediate analysis step towards producing pixel intensity distributions (FIG. 7).

FIG. 7 depicts examples of graphs 700, 702, 704, 706, 708, and 710 of different types of pixel value distributions of the image data (i.e., sets from which images 600, 602, and 604 are examples) in FIG. 6. The pixel value distributions are based on the values of the pixels in sets of which the images 600 (700, 702), 602 (704, 706), and 604 (708, 710) are examples. The horizontal axes of the graphs 700, 702, 704, 706, 708 and 710 represent the range of images in the image set (1-256). An image can also be called a “slice”. The vertical axes of the graphs 700, 704, and 708 represent the maximum pixel intensity value contained within each slice. The vertical axes of the graphs 702, 706, and 710 represent the fraction of pixels within each slice that have a high value (designated as >91 percent of the maximum possible) . . . . The pixel value distributions are utilized in determining if there is a hardware failure with the MR gradient subsystem.

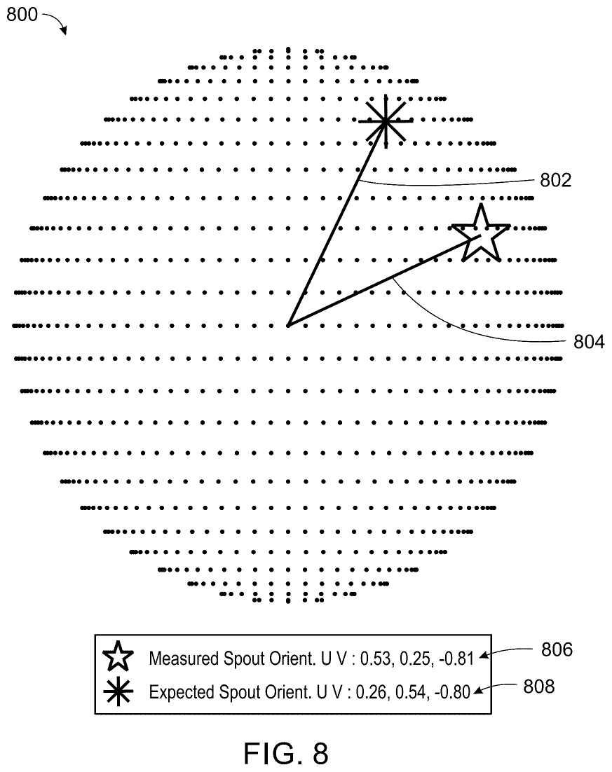

FIG. 8 depicts a feature analysis 800 on image data of a spherical phantom having an asymmetric feature and a comparison of measured and expected orientations of the spherical phantom. An expected orientation of a line from the center of the spherical phantom to a central location of the asymmetric feature of the spherical phantom is represented by reference numeral 802. A measured orientation of a line from the center of the spherical phantom to a central location of the asymmetric feature of the spherical phantom is represented by reference numeral 804. Below the feature analysis 800 are shown the measured values of the components of the unit vector of the line 804 (indicated by reference numeral 806) as well as the expected values of the components of the unit vector of the line 802 (indicated by reference numeral 808). As depicted, the first measured component is within the threshold of the second expected component (e.g., associated with the −Y-axis of the MR gradient subsystem). Also, as depicted, the second measured component is within the threshold of the first expected component (e.g., associated with the X-axis of the MR gradient subsystem). The third measured component is within the threshold for the third expected component. Thus, the comparison of the measured orientation and the expected orientation of the spherical phantom indicates that there is installation problem (e.g., that X-axis and the Y-axis portions of the MR gradient subsystem were incorrectly installed).

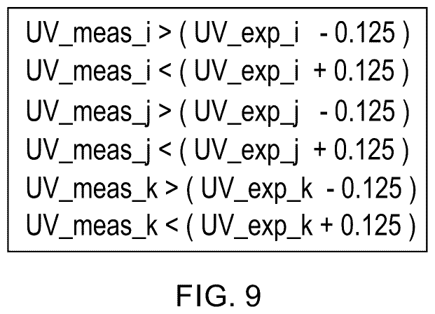

FIG. 9 depicts passing criteria for determining if an MR gradient subsystem is installed correctly. In FIG. 9, i, j, and k represent the values of the x, y, and z components of the unit vector. The ranges of the expected (exp) orientation measurements of the components i, j, and k are shown plus or minus 0.125. If each of the measured (meas) orientation measurements fall within these respective ranges then they pass the criteria and the MR gradient subsystem is correctly installed.

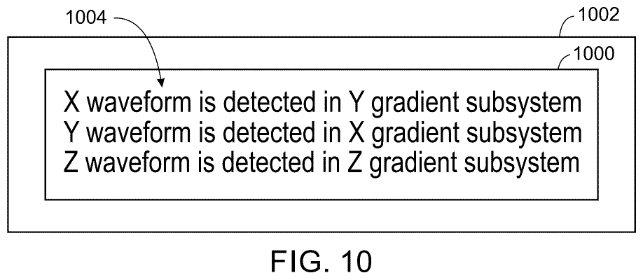

FIG. 10 is a graphical user interface 1000 on a display 1002 showing a report 1004 (e.g., provided to a user) of an analysis as to whether an MR gradient subsystem is installed correctly. The example report 1004 relates to installation of the MR gradient subsystem. The example report indicates there is an installation problem present with the MR gradient subsystem. In particular, the X waveform is detected in the Y gradient subsystem while the Y waveform is detected in the X gradient subsystem.

Technical effects of the disclosed subject matter include providing a general technique to diagnose any single one or a combination the X, Y, and Z coils/axes of the MR gradient subsystem for failures (e.g., wrong polarity, wrong connectivity, or non-operation (e.g., no transient magnetic field generated). Both hardware failures and installation problems can be detected and diagnosed. Technical effects of the disclosed subject matter include providing a precise diagnosis of what is wrong with the MR gradient subsystem. Technical effects of the disclosed subject matter include reducing cost by speeding up the troubleshooting process for incorrectly installed MR gradient subsystems or MR gradient subsystems with hardware failure. Technical effects of the disclosed subject matter include streamlining the resolution process.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform] ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

This written description uses examples to disclose the present subject matter, including the best mode, and also to enable any person skilled in the art to practice the subject matter, including making and using any devices or systems and performing any incorporated methods. The patentable scope of the subject matter is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A computer-implemented method for detecting an error with a magnetic resonance (MR) gradient subsystem, comprising:
acquiring, via a processing system comprising one or more processors, image data of a spherical phantom having an asymmetric feature during a scan utilizing an MR scanner having the MR gradient subsystem;
analyzing, via the processing system, pixel value distributions of the image data; and
determining, via the processing system, whether the MR gradient subsystem has a hardware failure based on the analysis of the pixel value distributions.

2. The computer-implemented method of claim 1, further comprising outputting, via the processing system, a user-perceptible indication of the hardware failure and ceasing, via the processing system, further analysis of the MR gradient subsystem when the MR gradient subsystem has hardware failure.

3. The computer-implemented method of claim 2, further comprising outputting, via the processing system, which of an X-axis, a Y-axis, and/or a Z-axis of the MR gradient subsystem has the hardware failure in the user-perceptible indication.

4. The computer-implemented method of claim 1, further comprising, when the MR gradient subsystem does not have any hardware failure, performing, via the processing system, feature analysis on the image data, wherein during the scan the spherical phantom was arranged within a bore of the MR scanner in a multi-axis-component orientation where a line extending from a center of the spherical phantom to a central location of the asymmetric feature has a contribution from each of an X-axis component, a Y-axis component, and a Z-axis component, wherein each respective contribution from the X-axis component, the Y-axis component, and the Z-axis component is different and has a value that is not zero.

5. The computer-implemented method of claim 4, further comprising determining, via the processing system, a measured orientation of the spherical phantom, wherein the measured orientation comprises measured respective contributions from the X-axis component, the Y-axis component, and the Z-axis component.

6. The computer-implemented method of claim 5, further comprising comparing, via the processing system, the measured orientation to an expected orientation of the spherical phantom, wherein the expected orientation comprises expected respective contributions from the X-axis component, the Y-axis component, and the Z-axis component when the MR gradient subsystem is installed properly.

7. The computer-implemented method of claim 6, further comprising determining, via the processing system, that the MR gradient subsystem is installed properly when the measured orientation is within a preset threshold of the expected orientation.

8. The computer-implemented method of claim 6, further comprising determining, via the processing system, that the MR gradient subsystem is not installed properly when the measured orientation is outside a preset threshold of the expected orientation.

9. The computer-implemented method of claim 8, further comprising outputting, via the processing system, a user-perceptible indication that the MR gradient subsystem is not installed properly and which of an X-axis, a Y-axis, and/or a Z-axis of the MR gradient subsystem is not installed properly.

10. A system for detecting an error with a magnetic resonance (MR) gradient subsystem, comprising:
a memory encoding processor-executable routines; and
a processing system comprising one or more processors and configured to access the memory and to execute the processor-executable routines, wherein the processor-executable routines, when executed by the processing system, cause the processing system to:
acquire image data of a spherical phantom having an asymmetric feature during a scan utilizing an MR scanner having the MR gradient subsystem;
analyze pixel value distributions of the image data; and
determine whether the MR gradient subsystem has a hardware failure based on the analysis of the pixel value distributions.

11. The system of claim 10, wherein the processor-executable routines, when executed by the processing system, further cause the processing system to output a user-perceptible indication of the hardware failure and cease further analysis of the MR gradient subsystem when the MR gradient subsystem has hardware failure.

12. The system of claim 11, wherein the processor-executable routines, when executed by the processing system, further cause the processing system to output which of an X-axis, a Y-axis, and/or a Z-axis of the MR gradient subsystem has the hardware failure in the user-perceptible indication.

13. The system of claim 10, wherein the processor-executable routines, when executed by the processing system, further cause the processing system, when the MR gradient subsystem does not have any hardware failure, to perform feature analysis on the image data, wherein during the scan the spherical phantom was arranged within a bore of the MR scanner in a multi-axis-component orientation where a line extending from a center of the spherical phantom to a central location of the asymmetric feature has a contribution from each of an X-axis component, a Y-axis component, and a Z-axis component, wherein each respective contribution from the X-axis component, the Y-axis component, and the Z-axis component is different and has a value that is not zero.

14. The system of claim 13, wherein the processor-executable routines, when executed by the processing system, further cause the processing system to determine a measured orientation of the spherical phantom, wherein the measured orientation comprises measured respective contributions from the X-axis component, the Y-axis component, and the Z-axis component.

15. The system of claim 14, wherein the processor-executable routines, when executed by the processing system, further cause the processing system to compare the measured orientation to an expected orientation of the spherical phantom, wherein the expected orientation comprises expected respective contributions from the X-axis component, the Y-axis component, and the Z-axis component when the MR gradient subsystem is installed properly.

16. The system of claim 15, wherein the processor-executable routines, when executed by the processing system, further cause the processing system to determine that the MR gradient subsystem is installed properly when the measured orientation is within a preset threshold of the expected orientation.

17. The system of claim 15, wherein the processor-executable routines, when executed by the processing system, further cause the processing system to determine, via the processing system, that the MR gradient subsystem is not installed properly when the measured orientation is outside a preset threshold of the expected orientation.

18. The system of claim 17, wherein the processor-executable routines, when executed by the processing system, further cause the processing system to output a user-perceptible indication that the MR gradient subsystem is not installed properly and which of an X-axis, a Y-axis, and/or a Z-axis of the MR gradient subsystem is not installed properly.

19. A non-transitory computer-readable medium, the non-transitory computer-readable medium comprising processor-executable code that when executed by a processing system comprising one or more processors, causes the processing system to:
acquire image data of a spherical phantom having an asymmetric feature during a scan utilizing an magnetic resonance (MR) scanner having an MR gradient subsystem;
analyze pixel value distributions of the image data; and
determine whether the MR gradient subsystem has a hardware failure based on the analysis of the pixel value distributions.

20. The non-transitory computer-readable medium of claim 19, wherein the processor-executable code, when executed by the processing system, further causes the processing system, when the MR gradient subsystem does not have any hardware failure, to:
perform feature analysis on the image data, wherein during the scan the spherical phantom was arranged within a bore of the MR scanner in a multi-axis-component orientation where a line extending from a center of the spherical phantom to a central location of the asymmetric feature has a contribution from each of an X-axis component, a Y-axis component, and a Z-axis component, wherein each respective contribution from the X-axis component, the Y-axis component, and the Z-axis component is different and has a value that is not zero;
determine a measured orientation of the spherical phantom, wherein the measured orientation comprises measured respective contributions from the X-axis component, the Y-axis component, and the Z-axis component; and
compare the measured orientation to an expected orientation of the spherical phantom to determine if the MR gradient subsystem is installed properly, wherein the expected orientation comprises expected respective contributions from the X-axis component, the Y-axis component, and the Z-axis component when the MR gradient subsystem is installed properly.
